(19) United States
(12) Patent Application Publication
(10) Pub. No.: US 2017/0170012 A1
(43) Pub. Date: Jun. 15, 2017

(54) METHOD OF INTERCALATING INSULATING LAYER BETWEEN METAL CATALYST LAYER AND GRAPHENE LAYER AND METHOD OF FABRICATING SEMICONDUCTOR DEVICE USING THE SAME

(71) Applicant: SAMSUNG ELECTRONICS CO., LTD., Suwon-si (KR)

(72) Inventors: Wonhee KO, Seoul (KR); Hyowon KIM, Seongnam-si (KR); Jiyeon KU, Suwon-si (KR); Insu JEON, Seoul (KR)

(73) Assignee: SAMSUNG ELECTRONICS CO., LTD., Suwon-si (KR)

(21) Appl. No.: 15/377,237

(22) Filed: Dec. 13, 2016

(30) Foreign Application Priority Data
Dec. 14, 2015 (KR) 10-2015-0178504

(51) Int. Cl. H01L 21/02; H01L 29/66; H01L 21/324; H01L 21/265

(52) U.S. Cl. CPC H01L 21/02527; H01L 21/26506; H01L 21/02614; H01L 29/66515; H01L 21/324

(57) ABSTRACT

Methods of intercalating an insulating layer between a metal catalyst layer and a graphene layer and methods of fabricating a semiconductor device using the intercalating method are provided. The method of intercalating the insulating layer includes forming the graphene layer on the metal catalyst substrate, intercalating nitrogen ions between the metal catalyst substrate and the graphene layer, and forming the insulating layer between the metal catalyst substrate and the graphene layer by heating the metal catalyst substrate to chemically combine the nitrogen ions with the metal catalyst substrate.

### CROSS-REFERENCE TO RELATED APPLICATION

This application claims priority from Korean Patent Application No. 10-2015-0178504, filed on Dec. 14, 2015, in the Korean Intellectual Property Office, the disclosure of which is incorporated herein by reference in its entirety.

### BACKGROUND

1. Field

Methods consistent with exemplary embodiments relate to intercalating an insulating layer between a metal catalyst layer and a graphene layer and methods of fabricating a semiconductor device using the intercalating methods.

2. Description of the Related Art

Graphene has a 2-dimensional hexagonal structure in which carbon atoms are connected in a hexagonal shape on a plane. Graphene has very stable electrical/mechanical/chemical characteristics and very high electrical conductivity, and thus, has received attention as a next generation material. Studies have been conducted to manufacture electronic devices by using graphene in place of silicon semiconductor.

Graphene may be directly grown on a surface of a metal catalyst substrate by using a chemical vapor deposition (CVD) method. To use graphene in a semiconductor device or a display apparatus, an operation of transferring graphene grown on a metal catalyst substrate onto a surface of another material, such as a non-conductor, is performed. The method may be performed, for example, after dissolving a metal catalyst substrate in a liquid solvent, and transferring remaining graphene on a surface of another material, or after detaching graphene from s metal catalyst substrate by using an adhesive stamp, and transferring the graphene attached to the adhesive stamp onto on a surface of another material.

However, the graphene may be damaged during the transferring processes.

### SUMMARY

Exemplary embodiments may address at least the above problems and/or disadvantages and other disadvantages not described above. Also, the exemplary embodiments are not required to overcome the disadvantages described above, and may not overcome any of the problems described above.

Exemplary embodiments provide methods of intercalating an insulating layer between a metal catalyst substrate and a graphene layer directly grown on the metal catalyst substrate.

Exemplary embodiments provide methods of manufacturing a semiconductor device by using the above methods.

According to an aspect of an exemplary embodiment, there is provided a method of intercalating an insulating layer between a metal catalyst layer and a graphene layer, the method including forming the graphene layer on the metal catalyst substrate, intercalating nitrogen ions between the metal catalyst substrate and the graphene layer, and forming the insulating layer between the metal catalyst substrate and the graphene layer by heating the metal catalyst substrate to chemically combine the nitrogen ions with the metal catalyst substrate.

The forming of the graphene layer may include growing the graphene layer in a single layer structure or a double layer structure.

The metal catalyst substrate may include any one or any combination of copper, nickel, platinum, cobalt, and iron.

The insulating layer may include nitride insulator crystals.

The metal catalyst substrate may include copper, and the insulating layer may include copper nitride.

The intercalating of the nitrogen ions between the metal catalyst substrate and the graphene layer may include injecting the nitrogen ions onto the graphene layer, using an ion gun.

The heating of the metal catalyst substrate may include heating the metal catalyst substrate to a temperature in a range from about 300° C. to about 400° C.

The forming of the insulating layer may include forming insulating units spaced apart from each other between the metal catalyst substrate and the graphene layer by performing the heating of the metal catalyst substrate, and forming the insulating layer including the insulating units connected to one another by repeatedly performing the intercalating of the nitrogen ions and the heating of the metal catalyst substrate four times or more.

Each of the insulating units may have a size of 5 nm or less.

The method may further include patterning the graphene layer.

According to an aspect of an exemplary embodiment, there is provided a method of manufacturing a transistor, the method including forming a graphene layer on a metal catalyst substrate, intercalating nitrogen ions between the metal catalyst substrate and the graphene layer, and forming a gate insulating layer between the metal catalyst substrate and the graphene layer by heating the metal catalyst substrate to chemically combine the nitrogen ions with the metal catalyst substrate. The method further includes patterning the graphene layer to expose the gate insulating layer, and forming a source electrode and a drain electrode on edges of the graphene layer.

The forming of the graphene layer may include growing the graphene layer in a single layer structure or a double layer structure.

The metal catalyst substrate may include any one or any combination of copper, nickel, platinum, cobalt, and iron.

The gate insulating layer may include nitride insulator crystals.

The metal catalyst substrate may include copper, and the gate insulating layer may include copper nitride.

The intercalating of the nitrogen ions between the metal catalyst substrate and the graphene layer may include injecting the nitrogen ions onto the graphene layer, using an ion gun.

The heating of the metal catalyst substrate may include heating the metal catalyst substrate to a temperature in a range from about 300° C. to about 400° C.

The forming of the gate insulating layer may include forming insulating units spaced apart from each other between the metal catalyst substrate and the graphene layer by performing the heating of the metal catalyst substrate, and forming the gate insulating layer including the insulating units connected to one another by repeatedly performing the intercalating of the nitrogen ions and the heating of the metal catalyst substrate four times or more.

Each of the insulating units may have a size of 5 nm or less.

### BRIEF DESCRIPTION OF THE DRAWINGS

The above and/or other aspects will become apparent and more readily appreciated from the following description of exemplary embodiments, taken in conjunction with the accompanying drawings in which:

FIGS. 1A, 1B, 1C, 1D, and 1E are schematic cross-sectional views illustrating a method of manufacturing an insulating layer between a metal catalyst substrate and a graphene layer, according to an exemplary embodiment;

FIG. 2 is a photograph showing a surface of a metal catalyst substrate after performing a nitrogen ion injection once and a thermal treatment, according to an exemplary embodiment; and

FIG. 3 is a schematic cross-sectional view illustrating a method of manufacturing a field effect transistor, according to an exemplary embodiment.

### DETAILED DESCRIPTION

Exemplary embodiments are described in greater detail below with reference to the accompanying drawings.

In the following description, like drawing reference numerals are used for like elements, even in different drawings. The matters defined in the description, such as detailed construction and elements, are provided to assist in a comprehensive understanding of the exemplary embodiments. However, it is apparent that the exemplary embodiments can be practiced without those specifically defined matters. Also, well-known functions or constructions are not described in detail because they would obscure the description with unnecessary detail.

In the drawings, thicknesses of layers and regions are exaggerated for clarity. The exemplary embodiments are capable of various modifications and may be embodied in many different forms.

It will also be understood that when an element is referred to as being “on” or “above” another element, the element may be in direct contact with the other element or other intervening elements may be present.

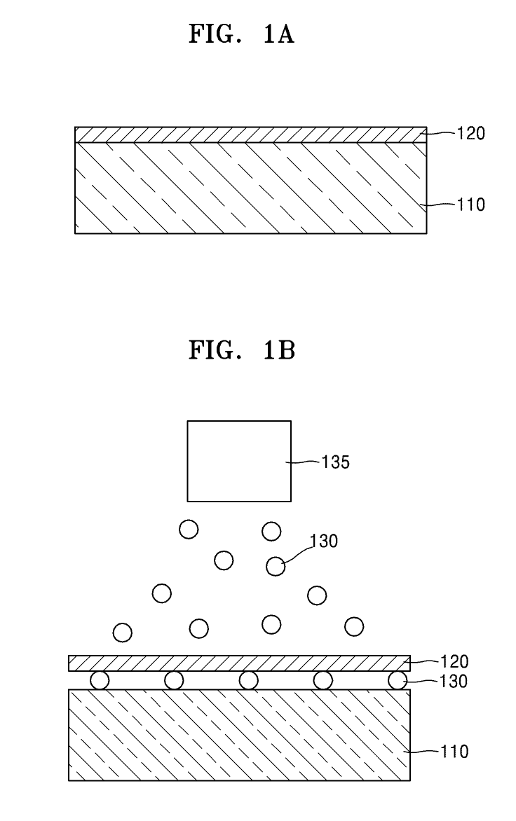

FIGS. 1A, 1B, 1C, 1D, and 1E are schematic cross-sectional views illustrating a method of manufacturing an insulating layer between a metal catalyst substrate 110 and a graphene layer 120, according to an exemplary embodiment.

Referring to FIG. 1A, the metal catalyst substrate 110 is prepared. The metal catalyst substrate 110 may be placed in a chamber. The chamber may be a chemical vapor deposition (CVD) chamber. The metal catalyst substrate 110 may include a catalyst on which graphene may be grown. For example, the metal catalyst substrate 110 may include copper Cu, nickel Ni, platinum Pt, cobalt Co, or iron Fe. Hereinafter, as an example, it is assumed that the metal catalyst substrate 110 includes copper Cu.

In FIG. 1A, the metal catalyst substrate 110 is prepared. However, the current exemplary embodiment is not limited thereto. For example, a metal catalyst layer may be formed on a first substrate. The first substrate may include glass, plastic, etc.

The graphene layer 120 is grown on the metal catalyst substrate 110. The graphene layer 120 may be grown by using the CVD method. A carbon containing gas may be supplied onto the metal catalyst substrate 110. The carbon containing gas may include CH₄, C₂H₂, C₂H₄, CO, etc. The method of manufacturing a graphene layer is well known in the art, and thus, a detailed description thereof will not be presented.

The graphene layer 120 may have a single layer structure or a double layer structure. As described below, if the graphene layer 120 is formed of more than three layers of graphene, an energy for intercalating nitrogen may increase.

Referring to FIG. 1B, nitrogen ions 130 are injected into a surface of the graphene layer 120. That is, nitrogen ions 130 are intercalated between the metal catalyst substrate 110 and the graphene layer 120. The injection of nitrogen ions 130 may be performed by using a sputtering process. For this purpose, after placing the metal catalyst substrate 110 in a sputtering chamber, the nitrogen ions 130 are injected onto the graphene layer 120 by using an ion gun 135. Nitrogen atoms may also be injected onto the graphene layer 120 together with the nitrogen ions 130. The nitrogen ion injection may be performed in a state of maintaining the sputtering chamber at an ultra vacuum condition of 10⁻⁹ torr or less.

The sputtering process may be performed under conditions in which an ion energy is 500 eV and an ion current is 1 μA. The injection of nitrogen ions 130 may be performed for 2 minutes. An area into which the nitrogen ions 130 are intercalated may vary according to sputtering conditions.

Referring to FIG. 1C, the metal catalyst substrate 110 is heated to a predetermined temperature, for example, in a range from about 300° C. to about 400° C. The injection of nitrogen ions 130 may be performed in a state that the sputtering chamber is heated to in a range from about 300° C. to about 400° C.

The nitrogen ions 130 are chemically combined with the metal catalyst substrate 110 formed of copper and form insulating units 140 on the metal catalyst substrate 110 in a thermal treating process. Each of the insulating units 140 has a size (i.e., a length) of 5 nm or less. The insulating units 140 are spaced apart from each other on the metal catalyst substrate 110. The insulating units 140 may include copper nitride Cu₃N.

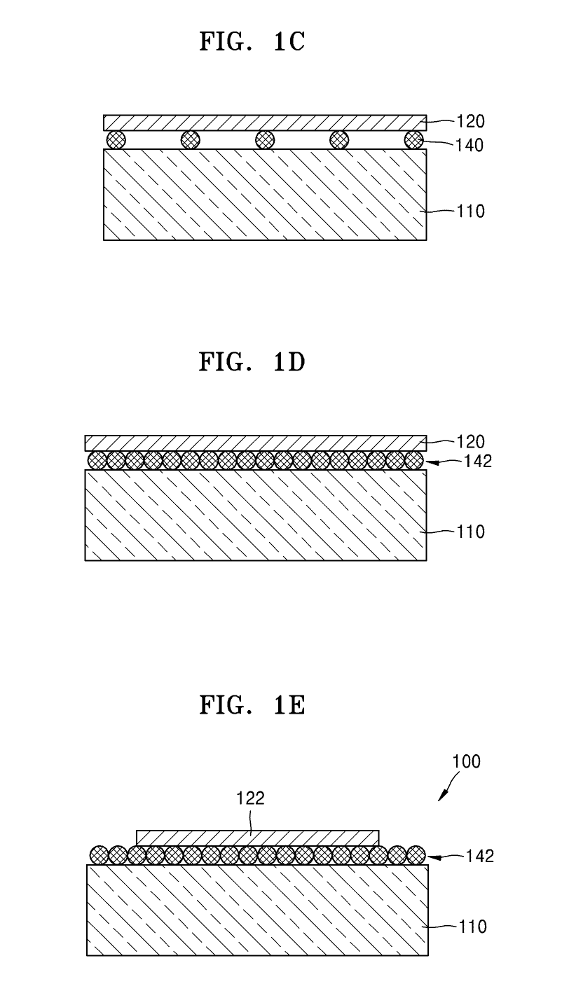

FIG. 2 is a photograph showing a surface of the metal catalyst substrate 110 after performing the nitrogen ion injection once and the thermal treatment, according to an exemplary embodiment. As depicted in FIG. 2, a plurality of Cu₃N insulating units is seen as black circles on the surface of the metal catalyst substrate 110.

Referring again to FIG. 1B, when the sputtering time of the nitrogen ions 130 is too long, the graphene layer 120 may be damaged by energy of the nitrogen ions 130 passing through the graphene layer 120.

Referring to FIG. 1D, to prevent the graphene layer 120 from being damaged, the sputtering process may be intermittently repeated. For example, while intermittently performing the sputtering process at an interval of 5 to 60 minutes, the metal catalyst substrate 110 may be maintained at the thermal treatment temperature. When the sputtering process is repeated for four times or more, the insulating units 140 that are formed between the graphene layer 120 and the metal catalyst substrate 110 may form a layer, that is, an insulating layer 142 by being connected to each other. The insulating layer 142 prevents a lower surface of the graphene layer 120 from contacting the metal catalyst substrate 110. The insulating layer 142 may be crystals of nitride insulators.

Referring to FIG. 1E, a graphene layer 122 of a desired pattern may be formed by patterning the graphene layer 120 formed on the metal catalyst substrate 110. For example, the graphene layer 120 may be patterned to a pattern for manufacturing a device. In this manner, a graphene stack structure 100 of metal/insulating layer/graphene layer may be formed.

However, the patterning of the graphene layer 120 is not an essential process, and according to exemplary embodiments, the patterning process may be omitted. Also, the sequence of performing the patterning the graphene layer 120 may be changed. For example, after the process depicted in FIG. 1A is completed, the graphene layer 120 may be patterned.

According to the exemplary embodiment, a nitride insulating layer may be formed between a metal catalyst substrate and a graphene layer in a short period of time. Also, the nitride insulating layer may be uniformly formed. The nitride insulating layer may further be helpful when a graphene layer is formed in a large area. It is unnecessary to separate the graphene layer from the metal catalyst substrate to transfer the graphene layer formed on the metal catalyst substrate to another target substrate. Accordingly, damage to or breakage of the graphene layer or infiltrations of impurities into the graphene layer that may occur in a process of transferring the graphene layer from the metal catalyst substrate to a surface of another material may be prevented. Accordingly, when a semiconductor device or a display apparatus is formed by using a graphene layer, the manufacturing process may be simplified and product yield may be increased. Also, the electrical characteristics of the graphene layer 120 may be maintained as they are, and thus, performances of a finally manufactured semiconductor device or a display apparatus may be improved.

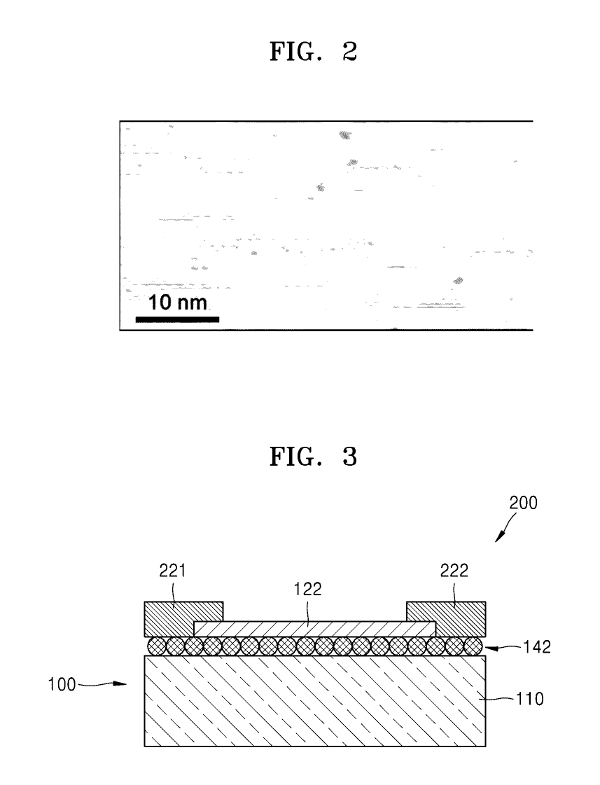

FIG. 3 is a schematic cross-sectional view of a method of manufacturing a field effect transistor 200, according to an exemplary embodiment.

Referring to FIG. 3, in the pattering process of the graphene layer 120 of FIG. 1E, the graphene layer 120 is patterned to a nano-ribbon shape. For example, the graphene layer 120 may be patterned so that the patterned graphene layer 122 has a band gap width in a range from about 1 nm to about 20 nm.

A source electrode 221 and a drain electrode 222 respectively are formed on both edges of the graphene layer 122 of the graphene stack structure 100 depicted in FIG. 1E. The source electrode 221 and the drain electrode 222 may be formed by using a well-known semiconductor manufacturing process, and thus, the detailed description thereof will not be repeated.

The metal catalyst substrate 110 may perform as a gate electrode, and the insulating layer 142 formed by an intercalation method between the metal catalyst substrate 110 and the graphene layer 122 may perform as a gate insulating layer. The graphene layer 122 may perform as a channel. Accordingly, when the exemplary embodiment is used, the field effect transistor 200 that uses the graphene layer 122 as a channel may be more easily manufactured.

According to the exemplary embodiment, a nitride insulating layer may be formed between a metal catalyst substrate and a graphene layer. Also, the nitride insulating layer may be uniformly formed.

To transfer a graphene layer formed on a metal catalyst substrate to another target substrate, it is unnecessary to separate the graphene layer from the metal catalyst substrate. Accordingly, damage to or breakage of the graphene layer or infiltration of impurities into the graphene layer that may occur in a process of transferring the graphene layer to a surface of another material from the metal catalyst substrate may be prevented.

While one or more embodiments have been described with reference to the figures, it will be understood by those of ordinary skill in the art that various changes in form and details may be made therein without departing from the spirit and scope as defined by the following claims.

What is claimed is:

1. A method of intercalating an insulating layer between a metal catalyst layer and a graphene layer, the method comprising:
forming the graphene layer on the metal catalyst substrate;
intercalating nitrogen ions between the metal catalyst substrate and the graphene layer; and
forming the insulating layer between the metal catalyst substrate and the graphene layer by heating the metal catalyst substrate to chemically combine the nitrogen ions with the metal catalyst substrate.

2. The method of claim 1, wherein the forming of the graphene layer comprises growing the graphene layer in a single layer structure or a double layer structure.

3. The method of claim 1, wherein the metal catalyst substrate comprises any one or any combination of copper, nickel, platinum, cobalt, and iron.

4. The method of claim 1, wherein the insulating layer comprises nitride insulator crystals.

5. The method of claim 1, wherein the metal catalyst substrate comprises copper, and
the insulating layer comprises copper nitride.

6. The method of claim 5, wherein the intercalating of the nitrogen ions between the metal catalyst substrate and the graphene layer comprises injecting the nitrogen ions onto the graphene layer, using an ion gun.

7. The method of claim 6, wherein the heating of the metal catalyst substrate comprises heating the metal catalyst substrate to a temperature in a range from about 300° C. to about 400° C.

8. The method of claim 6, wherein the forming of the insulating layer comprises:
forming insulating units spaced apart from each other between the metal catalyst substrate and the graphene layer by performing the heating of the metal catalyst substrate; and
forming the insulating layer comprising the insulating units connected to one another by repeatedly performing the intercalating of the nitrogen ions and the heating of the metal catalyst substrate four times or more.

9. The method of claim 8, wherein each of the insulating units has a size of 5 nm or less.

10. The method of claim 1, further comprising patterning the graphene layer.

11. A method of manufacturing a transistor, the method comprising:
forming a graphene layer on a metal catalyst substrate;
intercalating nitrogen ions between the metal catalyst substrate and the graphene layer;
forming a gate insulating layer between the metal catalyst substrate and the graphene layer by heating the metal catalyst substrate to chemically combine the nitrogen ions with the metal catalyst substrate;
patterning the graphene layer to expose the gate insulating layer; and
forming a source electrode and a drain electrode on edges of the graphene layer.

12. The method of claim 11, wherein the forming of the graphene layer comprises growing the graphene layer in a single layer structure or a double layer structure.

13. The method of claim 11, wherein the metal catalyst substrate comprises any one or any combination of copper, nickel, platinum, cobalt, and iron.

14. The method of claim 11, wherein the gate insulating layer comprises nitride insulator crystals.

15. The method of claim 1, wherein the metal catalyst substrate comprises copper, and
the gate insulating layer comprises copper nitride.

16. The method of claim 15, wherein the intercalating of the nitrogen ions between the metal catalyst substrate and the graphene layer comprises injecting the nitrogen ions onto the graphene layer, using an ion gun.

17. The method of claim 16, wherein the heating of the metal catalyst substrate comprises heating the metal catalyst substrate to a temperature in a range from about 300° C. to about 400° C.

18. The method of claim 16, wherein the forming of the gate insulating layer comprises:
forming insulating units spaced apart from each other between the metal catalyst substrate and the graphene layer by performing the heating of the metal catalyst substrate; and
forming the gate insulating layer comprising the insulating units connected to one another by repeatedly performing the intercalating of the nitrogen ions and the heating of the metal catalyst substrate four times or more.

19. The method of claim 18, wherein each of the insulating units has a size of 5 nm or less.
